(19) United States
(12) Patent Application Publication
(10) Pub. No.: US 2026/0121661 A1
(43) Pub. Date: Apr. 30, 2026

(54) ANTI-GHOSTING MEMBRANE KEYBOARD

(71) Applicant: SUNREX TECHNOLOGY CORP., Taichung City (TW)

(72) Inventors: Hsing-Kuang CHEN, Taichung City (TW); Chih-Cheng LEE, Taichung City (TW)

(73) Assignee: SUNREX TECHNOLOGY CORP., Taichung City (TW)

(21) Appl. No.: 19/079,312

(22) Filed: Mar. 13, 2025

(30) Foreign Application Priority Data
Oct. 30, 2024 (TW) 113141555

(51) Int. Cl. H03M 11/00; G06F 3/02; G06F 3/023; H01H 13/704; H01H 13/705

(52) U.S. Cl. CPC H03M 11/003; G06F 3/0202; G06F 3/023; H01H 13/704; H01H 13/705

(57) ABSTRACT

An anti-ghosting membrane keyboard includes a bottom membrane layer, a sensing circuit, and a top membrane layer. The sensing circuit includes a first circuit disposed on the bottom membrane layer, a plurality of flexible conductive elements disposed on the first circuit and spaced apart from each other, and a second circuit disposed on the flexible conductive elements. Each of the flexible conductive elements is a force-sensing resistor. The first circuit and the second circuit are spaced apart by the flexible conductive elements, and each of the flexible conductive elements is connected between a portion of the first circuit and a portion of the second circuit. The top membrane layer is disposed over the bottom membrane layer and the sensing circuit, and is adhered to the bottom membrane layer to cooperatively enclose the sensing circuit.

### CROSS-REFERENCE TO RELATED APPLICATION

This application claims priority to Taiwanese Invention Patent Application No. 113141555, filed on Oct. 30, 2024, the entire disclosure of which is incorporated by reference herein.

### FIELD

The disclosure relates to a membrane keyboard, and more particularly to an anti-ghosting membrane keyboard.

### BACKGROUND

A conventional keyboard with ghost key suppression (as described in U.S. Pat. No. 8,754,790 B2) includes a switch module, a comparator, an exchange unit and a processing module. The switch module includes a plurality of driving lines for receiving respectively a plurality of driving signals, a plurality of sensing lines, a plurality of switches and a plurality of resistors. The comparator includes a first input end, a second input end for receiving a reference signal, and an output end for outputting a comparison signal. The exchange unit is controlled by a control input to cause at least one of the sensing lines to be electrically connected to the first input end of the comparator. The processing module is configured to set at least a part of the driving signals, the reference signal and the control input such that the comparison signal is able to indicate whether at least one of the switches is in a conducting state, whether at least one switch in a group of the switches is in a conducting state, or whether a single one of the switches is in a conducting state, in order to prevent an occurrence of “ghosting.”

Over time, membrane keyboards have gradually developed and become a prevalent type of keyboard; however, membrane keyboards also require measures to prevent the occurrence of “ghosting”. Referring to FIGS. 1, 2 and 3, a membrane unit 1 for a conventional membrane keyboard includes a bottom membrane layer 11, a middle membrane layer 12 disposed on the bottom membrane layer 11, and a top membrane layer 13 disposed on the middle membrane layer 12. The bottom membrane layer 11 has a top surface 111, and includes a first circuit 112 and a plurality of resistors (not shown) disposed on the top surface 111. The middle membrane layer 12 is formed with a plurality of conducting slots 122 (only one is shown in FIG. 1) for placing anisotropic conductive glue (not shown) therein, and a plurality of switching slots 121 (only one is shown in FIG. 1). The top membrane layer 13 has a bottom surface 131, and includes a second circuit 132 disposed on the bottom surface 131. The middle membrane layer 12 is disposed to prevent a short circuit between the first circuit 112 and the second circuit 132. Each of the switching slots 121 corresponds to a portion of the first circuit 112 and to a portion of the second circuit 132.

The top membrane layer 13 has a plurality of locations on the top membrane layer 13 that correspond respectively to the switching slots 121. During an operation of the conventional membrane keyboard, when a force is applied onto one of the locations on the top membrane layer 13 that corresponds to a respective one of the switching slots 121, the portion of the first circuit 112 that corresponds to the respective one of the switching slots 121 and the portion of the second circuit 132 that corresponds to the respective one of the switching slots 121 form an electrical connection with each other. The aforementioned configuration of the conventional membrane keyboard provides the same function as the conventional keyboard where one of the switches of the switch module is turned on when a button that corresponds to the one of the switches is depressed.

The first circuit 112 and the second circuit 132 are respectively disposed on the top surface 111 of the bottom membrane layer 11 and the bottom surface 131 of the top membrane layer 13, and are spaced apart from each other. Therefore, the anisotropic conductive glue is placed between the first circuit 112 and the second circuit 132 so that the first circuit 112 and the second circuit 132 may be electrically connected to each other, thereby realizing a “ghost key” prevention capability similar to that of the driving lines, the sensing lines, and the resistors of the conventional keyboard.

However, for the conventional membrane keyboard to have the “ghost key” prevention capability, at least three layers of membrane layers are required in the conventional membrane keyboard, which leads to difficulty in reducing the overall material cost. Moreover, an assembly process of the conventional membrane keyboard is quite complicated, further increasing the time required for the assembly process. Clearly, there is still room for improvement in the conventional membrane keyboard.

### SUMMARY

Therefore, an object of the disclosure is to provide an anti-ghosting membrane keyboard that can alleviate at least one of the drawbacks of the prior art.

According to the disclosure, the anti-ghosting membrane keyboard includes a bottom membrane layer, a sensing circuit, and a top membrane layer. The sensing circuit includes a first circuit disposed on the bottom membrane layer, a plurality of flexible conductive elements disposed on the first circuit, and a second circuit disposed on the flexible conductive elements. The flexible conductive elements are spaced apart from each other, and each of the flexible conductive elements is a force-sensing resistor. The first circuit and the second circuit are spaced apart by the flexible conductive elements, and each of the flexible conductive elements are connected between a portion of the first circuit and a portion of the second circuit. The top membrane layer is disposed over the bottom membrane layer and the sensing circuit, and is adhered to the bottom membrane layer to cooperatively enclose the sensing circuit.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is an exploded view of a membrane unit of a conventional membrane keyboard.

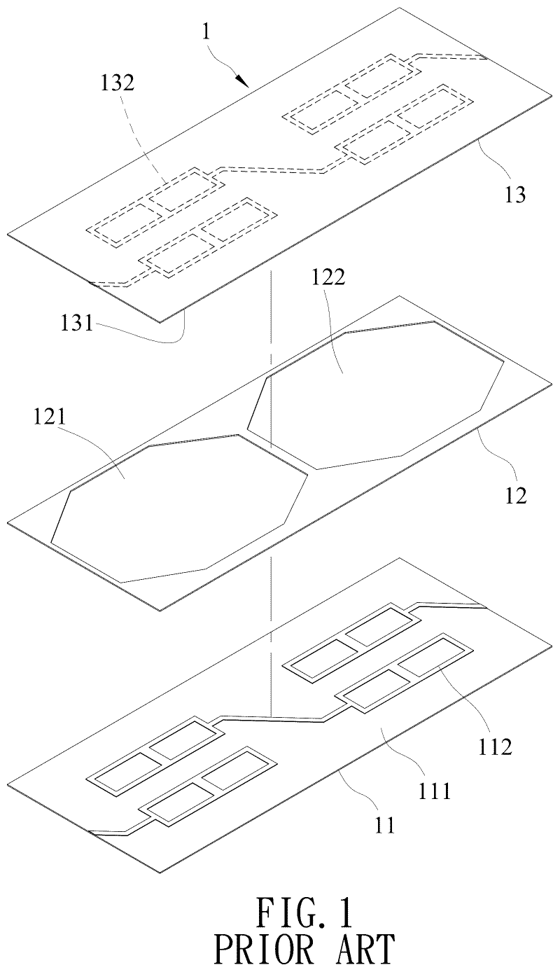

FIG. 2 is a perspective view of the membrane unit of the conventional membrane keyboard.

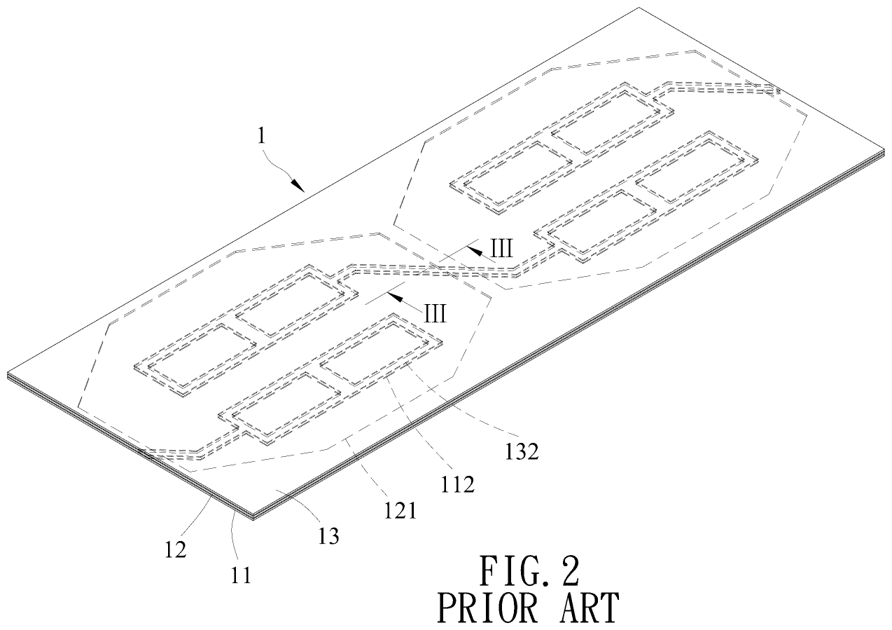

FIG. 3 is a fragmentary cross-sectional view taken along line III-III in FIG. 2.

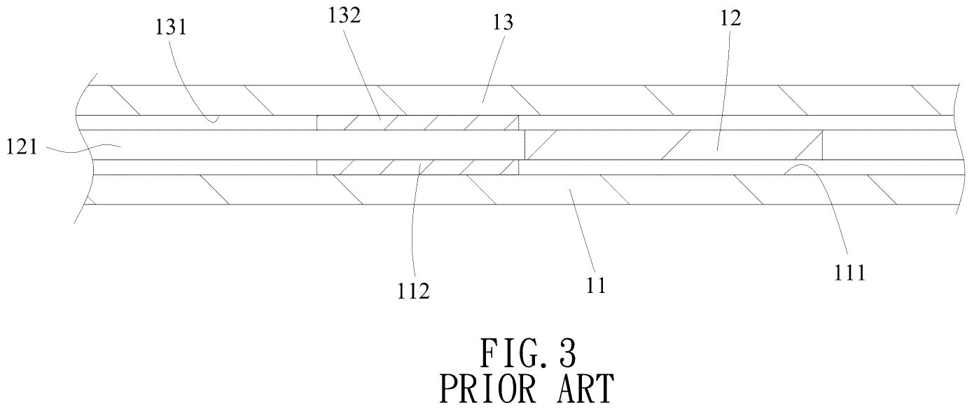

FIG. 4 is an exploded view of an anti-ghosting membrane keyboard according to an embodiment of the present disclosure.

FIG. 5 is an exploded view of a sensing circuit of the anti-ghosting membrane keyboard according to an embodiment of the present disclosure.

FIG. 6 is a fragmentary cross-sectional view of the anti-ghosting membrane keyboard according to an embodiment of the present disclosure.

FIG. 7 is a schematic diagram of the anti-ghosting membrane keyboard according to an embodiment of the present disclosure.

FIG. 8 is a schematic diagram similar to FIG. 7, illustrating an example of a flow of electric power when a processing unit of the anti-ghosting membrane keyboard supplies the electric power to one of driving lines of a sensing circuit.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

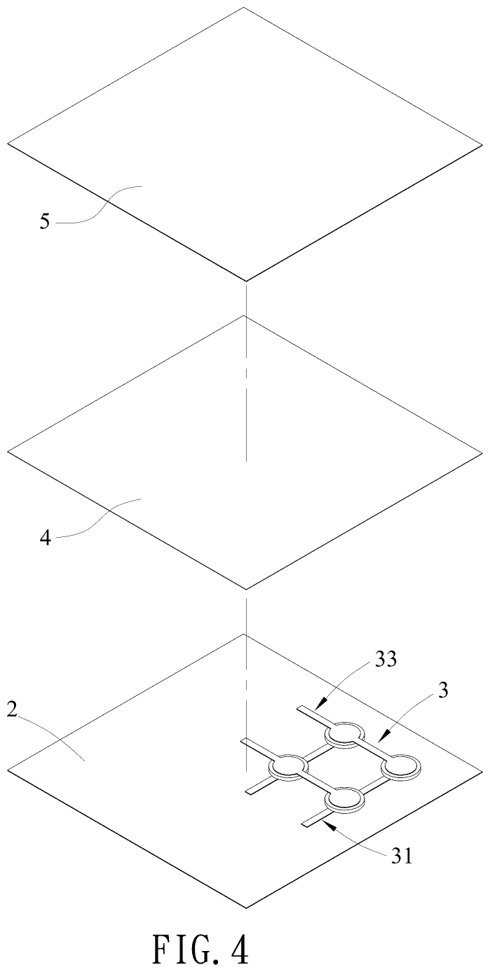

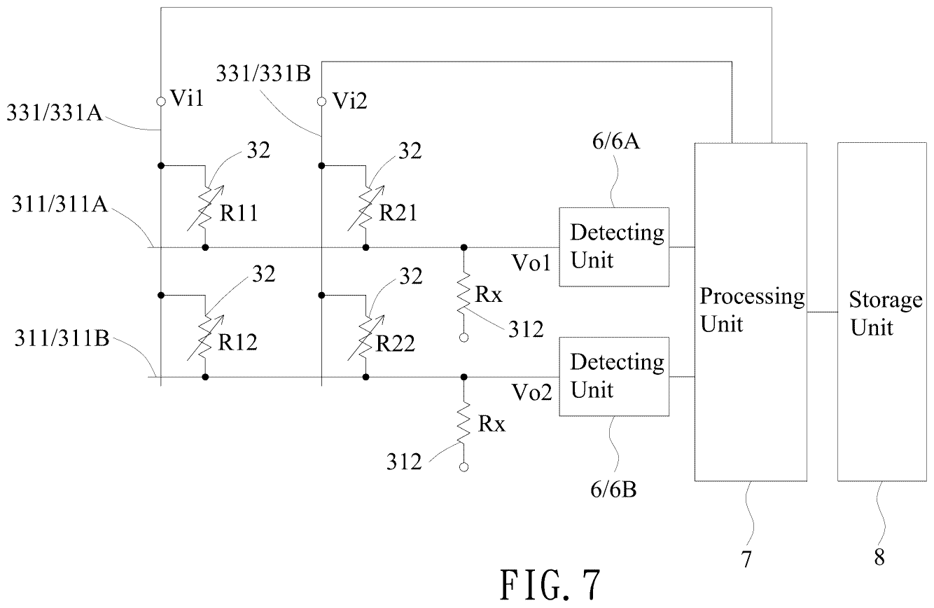

Referring to FIGS. 4 and 7, an anti-ghosting membrane keyboard according to an embodiment of the present disclosure includes a bottom membrane layer 2, a sensing circuit 3, a middle membrane layer 4, a top membrane layer 5, a plurality of detecting units 6, a processing unit 7, and a storage unit 8.

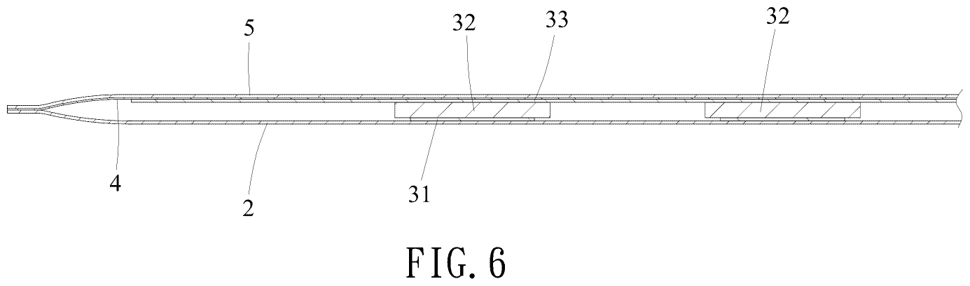

Referring to FIGS. 4 to 6, the sensing circuit 3 includes a first circuit 31 disposed on the bottom membrane layer 2, a plurality of flexible conductive elements 32 disposed on the first circuit 31 and spaced apart from each other, and a second circuit 33 disposed on the flexible conductive elements 32. Each of the flexible conductive elements 32 is a force-sensing resistor (FSR). The first circuit 31 and the second circuit 33 are spaced apart by the flexible conductive elements 32. The bottom membrane layer 2 may be exemplified by a polyester film made of, for example, polyethylene terephthalate (PET) material.

Further referring to FIG. 7, in this embodiment, the first circuit 31 includes a plurality of sensing lines 311, and a plurality of voltage divider resistors 312 electrically connected respectively to the sensing lines 311. The second circuit 33 includes a plurality of driving lines 331 for transferring electric power to the flexible conductive elements 32. The sensing lines 311 and the driving lines 331 are arranged in an intersecting manner (i.e., the sensing lines 311 all extend in a first direction, while the driving lines 331 all extend in a second direction that is perpendicular to the first direction), and are electrically connected through the flexible conductive elements 32, without overlapping or causing any short circuit.

In some embodiments, positions respectively of the first circuit 31 and the second circuit 33 may interchange. That is to say, in those embodiments, the second circuit 33 may be disposed on the bottom membrane layer 2, and the first circuit 31 may be disposed on the flexible conductive elements 32, such that when the sensing circuit 3 and the bottom membrane layer 2 form a stacked structure, the stacked structure is arranged in the sequence of, from top to bottom, the first circuit 31 including the sensing lines 311 and the voltage divider resistors 312, the flexible conductive elements 32, the second circuit 33 including the driving lines 331, and the bottom membrane layer 2.

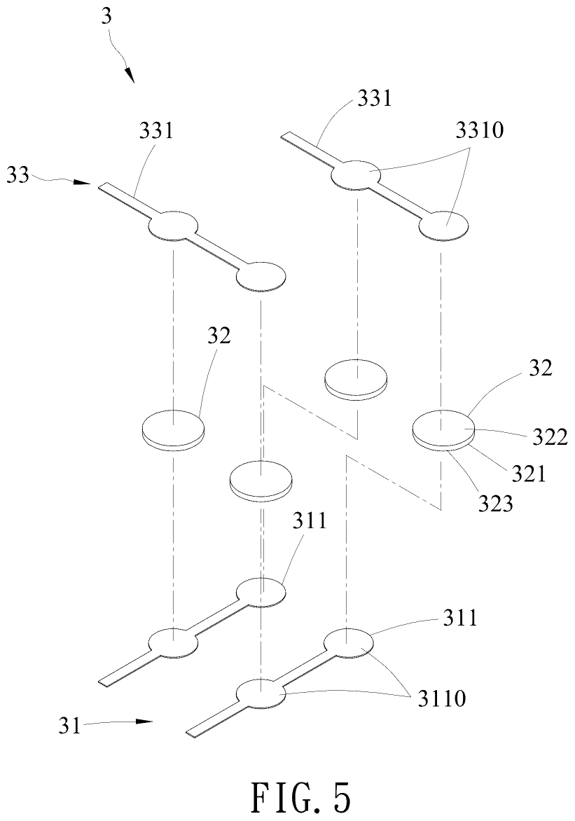

Referring to FIGS. 5, 6 and 7, each of the flexible conductive elements 32 is connected between a portion of the first circuit 31 and a portion of the second circuit 33, wherein each of the flexible conductive elements 32 is electrically connected between one of the sensing lines 311 and one of the driving lines 331. Specifically, each of the sensing lines 311 has a plurality of connection portions 3110 that correspond respectively to the driving lines 331, each of the driving lines 331 has a plurality of connection portions 3310 that correspond respectively to the sensing lines 311, and the flexible conductive elements 32 are disposed respectively on the connection portions 3110 of the sensing lines 311. That is to say, the connection portions 3110 of the sensing lines 311 are aligned respectively with the connection portions 3310 of the driving lines 331 in a top-bottom direction, and each the flexible conductive elements 32 is sandwiched in between a respective one of the connection portions 3110 of the sensing lines 311 and a corresponding one of the connection portions 3310 of the driving lines 331. Each of the flexible conductive elements 32 includes a bottom surface 321 in contact with the first circuit 31 (i.e., the connection portion 3110), a top surface 322 opposite to the bottom surface 321 and in contact with the second circuit 33 (i.e., the connection portion 3310), and a lateral surrounding surface 323 interconnecting the bottom surface 321 and the top surface 322. For each of the flexible conductive elements 32, when a distance between the top surface 322 and the bottom surface 321 is reduced in response to a force applied onto the top surface 322, a value of resistance of the flexible conductive element 32 is thereby reduced. In this embodiment, each of the flexible conductive elements 32 is exemplified by an elastic thin-film resistor made of a soft, thin polymer mixed with conductive particles, such as carbon nanotubes.

The middle membrane layer 4 is disposed on the bottom membrane layer 2 and the sensing circuit 3, is disposed beneath the top membrane layer 5, and adheres the bottom membrane layer 2, the sensing circuit 3 and the top membrane layer 5 to each other.

The top membrane layer 5 is disposed on the middle membrane layer 4, and over the bottom membrane layer 2 and the sensing circuit 3. The top membrane layer 5 is adhered to the bottom membrane layer 2 via the middle membrane layer 4 to cooperatively enclose the sensing circuit 3. Each of the bottom membrane layer 2 and the top membrane layer 5 may be exemplified by a polyester film made of, for example, polyethylene terephthalate (PET) material.

The detecting units 6 are electrically connected to the sensing circuit 3. In this embodiment, the detecting units 6 are electrically connected respectively to the sensing lines 311 and respectively to the voltage divider resistors 312 for receiving a plurality of divided voltage values that correspond respectively to the sensing lines 311. Specifically, each of the sensing lines 311 and a corresponding one of the voltage divider resistors 312 have a common point, and the detecting units 6 are electrically connected respectively to the common points between the sensing lines 311 and the voltage divider resistors 312 for receiving respectively the plurality of divided voltage values from the common points. For each of the detecting units 6, the detecting unit 6, in response to receipt of one of the divided voltage values from a corresponding one of the sensing lines 311, obtains a potential level value based on said one of the divided voltage values thus received, and transmits the potential level value thus obtained to the processing unit 7. In this embodiment, each of the detecting units 6 is exemplified as an analog-to-digital converter with 12-bit resolution, which can divide analog signals into 2¹² levels (i.e., 4096 levels). In some embodiments, a resolution requirement of each of the detecting units 6 is positively correlated with a number of the driving lines 331 and a number of the sensing lines 311, that is, the higher the number of the driving lines 331 and the number of the sensing lines 311, the higher the resolution requirement of each of the detecting units 6. In this embodiment, a number of the detecting units 6, the number of the driving lines 331, and the number of the sensing lines 311 are the same, but the disclosure is not limited in this respect, and the number of the detecting units 6, the number of the driving lines 331 and the number of the sensing lines 311 may be adjusted according to requirements.

The processing unit 7 is electrically connected to the detecting units 6 for receiving the potential level values respectively from the detecting units 6, and is further electrically connected to the driving lines 331 for supplying the electric power thereto. Specifically, the processing unit 7 supplies the electric power to the driving lines 331 one by one, and each time the processing unit 7 supplies the electric power to one of the driving lines 331, for each of the detecting units 6, the detecting unit 6 receives one of the divided voltage values from a corresponding one of the sensing lines 311 (i.e., from the common point between the sensing line 311 and the corresponding voltage divider resistor 312), obtains the potential level value based on the one of the divided voltage values thus received, and transmits the potential level value thus obtained to the processing unit 7. In this embodiment, the processing unit 7 may be exemplified by, for example, a field-programmable gate array (FPGA), a microprocessor, or a system-on-chip (SoC), but the disclosure is not limited to such.

The storage unit 8 is electrically connected to the processing unit 7. In this embodiment, the storage unit 8 is exemplified as a read-only memory (e.g., a flash memory), but the disclosure is not limited to such.

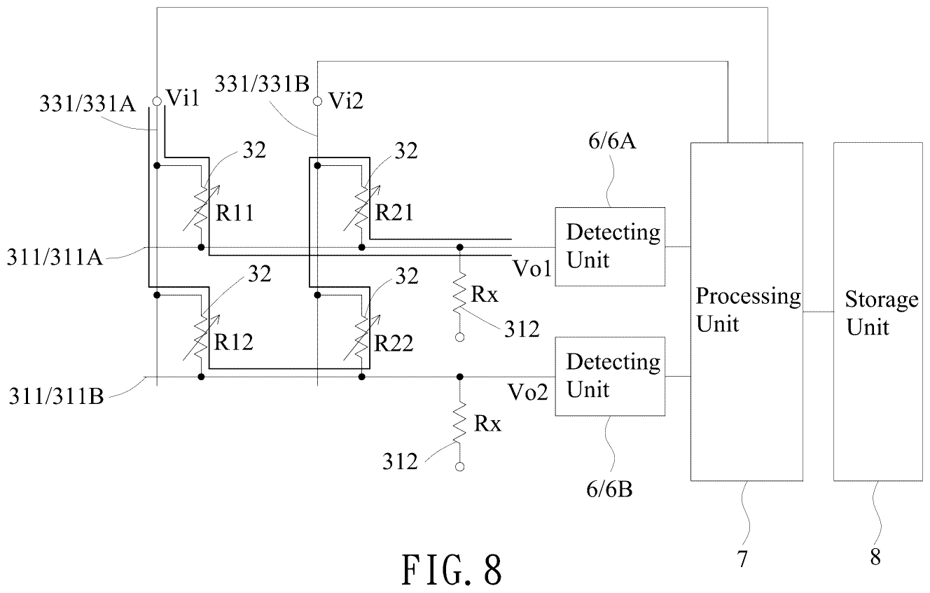

Referring to FIGS. 7 and 8, for illustration purposes, each of the number of the sensing lines 311, the number of the driving lines 331, and the number of the detecting units 6 is taken as two for example. Accordingly, a number of the flexible conductive elements 32, as well as a number of the connection portions 3110 of the sensing lines 311 and a number of the connection portions 3310 of the driving lines 331, is four (i.e., the number of the sensing lines 311 multiplied by the number of the driving lines 331) (see FIG. 5). For ease of illustration, the driving lines 331 includes a first driving line (331A) and a second driving line (331B), and the sensing lines 311 includes a first sensing line (311A) and a second sensing line (311B); the detecting units 6 includes a first detecting unit (6A) that is electrically connected to the first sensing line (311A), and a second detecting unit (6B) that is electrically connected to the second sensing line (311B); the electric power supplied by the processing unit 7 to the first driving line (331A) has a first input voltage (Vi1), and the electric power supplied by the processing unit 7 to the second driving line (331B) has a second input voltage (Vi2); one of the divided voltage values that corresponds to the first sensing line (311A) and is received by the first detecting unit (6A) is denoted by Vo1, and another one of the divided voltage values that corresponds to the second sensing line (311B) and is received by the second detecting unit (6B) is denoted by Vo2; each of the voltage divider resistors 312 has a resistance value denoted by Rx; the flexible conductive element 32 between the first driving line (331A) and the first sensing line (311A) has a resistance value denoted by R11, the flexible conductive element 32 between the first driving line (331A) and the second sensing line (311B) has a resistance value denoted by R12, the flexible conductive element 32 between the second driving line (331B) and the first sensing line (311A) has a resistance value denoted by R21, and the flexible conductive element 32 between the second driving line (331B) and the second sensing line (311B) has a resistance value denoted by R22. In this embodiment, for each of the flexible conductive elements 32, the resistance value is 2 KΩ when not depressed and 1.8 KΩ when depressed. The resistance value of each of the voltage divider resistors 312 is 1 KΩ (i.e., Rx=1 KΩ).

The following paragraphs illustrate an operation method of the anti-ghosting membrane keyboard according to the embodiments of this disclosure, and the operation method include steps S1 to S5.

In step S1, the processing unit 7 supplies the electric power to the driving lines 331 one by one. Referring to FIG. 8, the processing unit 7 first supplies the electric power to the first driving line (331A).

In step 2, the detecting units 6 receive the divided voltage values respectively from the first and second sensing lines (311A, 311B). A method of calculating the divided voltage values received respectively from the first and second sensing lines (311A, 311B) by the first and second detecting units (6A, 6B) is described below.

For ease of illustration, hereinafter, a total resistance value of a parallel connection between two resistors having resistance values R1 and R2 will be denoted as R1//R2, and calculated as

$$\frac{R 1 \times R 2}{R 1 + R 2} .$$

Referring to FIG. 8, for the first detecting unit (6A), the first divided voltage (Vo1) is calculated using the equation:

$$Vo 1 = \frac{Rx}{R 11 // ( R 12 + R 21 + R 22 ) + Rx} \times Vi 1 ,$$

where R11//(R12+R21+R22) denotes a total resistance value of a parallel connection between the flexible conductive element 32 whose resistance value is R11 (hereinafter referred to as “the first FSR”) and a series connection of the other flexible conductive elements 32 whose resistance values are respectively R12, R21 and R22. The total resistance value in this case is calculated as

$$\frac{R 11 ( R 12 + R 21 + R 22 )}{R 11 + R 12 + R 21 + R 22} .$$

From the aforementioned equation of calculating the first divided voltage (Vo1), it can be realized that, as compared to a change in each of R12, R21, R22, a change in R11 results in a greater change in the total resistance value of the parallel connection between the first FSR 32 and the series connection of the other flexible conductive elements 32. Accordingly, the change in R11 exerts a relatively greater influence on an overall voltage division ratio

$$\frac{Vo 1}{Vi 1}$$

of the first divided voltage (Vo1) to the first input voltage (Vi1). Therefore, changes in the overall voltage division ratio

$$\frac{Vo 1}{Vi 1}$$

may indicate whether the first FSR 32 is depressed.

Similarly, for the second detecting unit (6B), the second divided voltage (Vo2) is calculated using the equation:

$$Vo 2 = \frac{Rx}{R 12 // ( R 11 + R 21 + R 22 ) + Rx} \times Vi 1.$$

It can be realized that, compared to changes in each R11, R21, R22, a change in R12 results in a greater change in a total resistance value of a parallel connection between the flexible conductive element 32 whose resistance value is R12 (hereinafter referred to as “the second FSR”) and a series connection of the other flexible conductive elements 32 whose resistance values are respectively R11, R21 and R22. Accordingly, a change in R12 exerts a greater influence on an overall voltage division ratio

$$\frac{Vo 2}{Vi 1}$$

of the second divided voltage (Vo2) to the first input voltage (Vi1). Therefore, changes in the overall voltage division ratio

$$\frac{Vo 2}{Vi 1}$$

may indicate whether the second FSR 32 is depressed.

On the basis of the above way of calculating the first divided voltage (Vo1) and the second divided voltage (Vo2), when the processing unit 7 then supplies the electric power to the second driving line (331B), the first divided voltage (Vo1) may be calculated using the equation:

$$Vo 1 = \frac{Rx}{R 21 // ( R 11 + R 21 + R 22 ) + Rx} \times Vi 2.$$

It may be observed that, compared to a change in each of R11, R12, R22, a change in R21 results in a greater change in a total resistance value of a parallel connection between the flexible conductive element 32 whose resistance value is R21 (hereinafter referred to as “the third FSR”) and a series connection of the other flexible conductive elements 32 whose respective resistance values are respectively R11, R12 and R22. Accordingly, a change in R21 exerts a relatively greater influence on an overall voltage division ratio

$$\frac{Vo 1}{Vi 2}$$

of the first divided voltage (Vo1) to the second input voltage (Vi2). Therefore, changes in the overall voltage division ratio

$$\frac{Vo 1}{Vi 2}$$

may indicate whether the third FSR 32 is being depressed.

Similarly, when the processing unit 7 then supplies the electric power to the second driving line (331B), the second detecting unit (6B) may calculate the second divided voltage (Vo2) using the equation:

$$Vo 2 = \frac{Rx}{R 22 // ( R 11 + R 12 + R 21 ) + Rx} \times Vi 2.$$

It can be realized that, compared to a change in each of R11, R12, R21, a change in R22 results in a greater change in a total resistance value of a parallel connection between the flexible conductive element 32 whose resistance value is R22 (hereinafter referred to as “the fourth FSR”) and a series connection of the other flexible conductive elements 32 whose resistance values are respectively R11, R12 and R21. Accordingly, a change in R22 exerts a relatively greater influence on an overall voltage division ratio

$$\frac{Vo 2}{Vi 2}$$

of the second divided voltage (Vo2) to the second input voltage (Vi2). Therefore, changes in the overall voltage division ratio

$$\frac{Vo 2}{Vi 2}$$

may indicate whether the fourth FSR 32 is depressed.

It should be noted that the first input voltage (Vi1) and the second input voltage (Vi2) outputted by the processing unit 7 are substantially the same, and a difference in their designations is only used to distinguish them in the above calculation of the equations. When the processing unit 7 first supplies the first input voltage (Vi1) to the first driving line (331A), the first and second detecting units (6A, 6B) obtain

$$\frac{Vo 1}{Vi 1} and \frac{Vo 2}{Vi 1} ;$$

when the processing unit 7 then supplies the second input voltage (Vi2) to the second driving line (331B), the first and second detecting units (6A, 6B) obtain

$$\frac{Vo 1}{Vi 2} , and \frac{Vo 2}{Vi 2} .$$

Given that, in this embodiment, Rx is 1 KΩ, and R11, R12, R21, R22 are each 2 KΩ when the respective flexible conductive element 32 is not depressed and 1.8 KΩ when the respective flexible conductive element 32 is depressed as mentioned above; when none of the flexible conductive elements 32 is depressed,

$$\frac{V o 1}{Vi 1} , \frac{Vo 2}{Vi 1} , \frac{Vo 1}{Vi 2} , and \frac{Vo 2}{Vi 2}$$

are each 0.4; when the first FSR 32, whose resistance value is R11, is depressed,

$$\frac{Vo 1}{Vi 1} , \frac{Vo 2}{Vi 1} , \frac{Vo 1}{Vi 2} , and \frac{Vo 2}{Vi 2}$$

are respectively 0.419, 0.402, 0.402, and 0.402; when the first FSR 32 and the second FSR 32, whose resistance values are R11 and R12, are depressed,

$$\frac{Vo 1}{Vi 1} , \frac{Vo 2}{Vi 1} , \frac{Vo 1}{Vi 2} , and \frac{Vo 2}{Vi 2}$$

are respectively, after rounding to a third decimal place, 0.421, 0.421, 0.404, and 0.404. It can be seen from

$$\frac{Vo 1}{Vi 1} , \frac{Vo 2}{Vi 1} , \frac{Vo 1}{Vi 2} , and \frac{Vo 2}{Vi 2}$$

that, when multiple of the flexible conductive elements 32 are depressed at the same time, the divided voltage values corresponding to the flexible conductive elements 32 that are depressed at the same time are substantially the same since the first input voltage (Vi1) and the second input voltage (Vi2) are substantially the same.

In step S3, for each of the detecting units 6, when the detecting unit 6 receives the divided voltage value from the corresponding one of the sensing lines 311 (corresponding to a timing when the first input voltage (Vi1) is supplied to the first driving line (331A) or corresponding to a timing when the second input voltage (Vi2) is supplied to the second driving line (331B)), the detecting unit 6 obtains the potential level value based on the divided voltage value thus received, and transmits the potential level value to the processing unit 7. Specifically, when the processing unit 7 first supplies the first input voltage (Vi1) to the first driving line (331A), the first and second detecting units (6A, 6B) convert

$$\frac{Vo 1}{Vi 1} , and \frac{Vo 2}{Vi 1}$$

respectively into two potential level values and transmit the two potential level values to the processing unit 7; when the processing unit 7 then supplies the second input voltage (Vi2) to the second driving line (331B), the first and second detecting units (6A, 6B) convert

$$\frac{Vo 1}{Vi 2} , and \frac{Vo 2}{Vi 2}$$

respectively into another two potential level values and transmit said another two potential level values to the processing unit 7. Specifically, for each of the detecting units 6, each of

$$\frac{Vo 1}{Vi 1} , \frac{Vo 2}{Vi 1} , \frac{Vo 1}{Vi 2} , and \frac{Vo 2}{Vi 2} ,$$

is mapped to a potential level value based on the resolution (i.e., 4096) of the detecting unit 6, where the potential level value thus generated by the detecting unit 6 is equivalent to a respective one of

$$\frac{Vo 1}{Vi 1} , \frac{Vo 2}{Vi 1} , \frac{Vo 1}{Vi 2} , and \frac{Vo 2}{Vi 2} .$$

In other words, when none of the flexible conductive elements 32 are depressed, the potential level values received from the detecting units 6 that are equivalent to

$$\frac{Vo 1}{Vi 1} , \frac{Vo 2}{Vi 1} , \frac{Vo 1}{Vi 2} , and \frac{Vo 2}{Vi 2}$$

are each 1638; when the first FSR 32 is depressed, the potential level values that are equivalent respectively to

$$\frac{Vo 1}{Vi 1} , \frac{Vo 2}{Vi 1} , \frac{Vo 1}{Vi 2} , and \frac{Vo 2}{Vi 2}$$

are 1716, 1647, 1647, and 1647; when the first FSR 32 and the second FSR 32 are depressed at the same time, the potential level values that are equivalent respectively to

$$\frac{Vo 1}{Vi 1} , \frac{Vo 2}{Vi 1} , \frac{Vo 1}{Vi 2} , and \frac{Vo 2}{Vi 2}$$

are 1724, 1724, 1655, and 1655.

In step S4, the processing unit 7, for each of the detecting units 6, in response to receipt of the potential level value from the detecting unit 6, calculates a value difference between the potential level value thus received and a predetermined potential level value. In this embodiment, the predetermined potential level value is equivalent to the potential level value of each of the flexible conductive elements 32 when none of the flexible conductive elements 32 is depressed (i.e., 1638).

In step S5, for each of the potential level values received respectively from the detecting units 6, after the processing unit 7 has calculated the value difference, the processing unit 7 first determines whether the value difference is greater than a predetermined threshold value, and then determines whether the value difference is greater than a floating threshold value. Specifically, for one of the flexible conductive elements 32 that is electrically connected to the corresponding one of the sensing lines 311 from which said one of the divided voltage values is received and that is electrically connected to one of the driving lines 331 to which the processing unit 7 is supplying the electric power, the processing unit 7 determines that said one of the flexible conductive elements 32 is depressed in response to determining that the value difference is greater than the predetermined threshold value and the floating threshold value. The processing unit 7 then stores in the storage unit 8, a first-keys result data set that includes results related to whether the first FSR 32 (whose resistance value is R11) and/or the second FSR 32 (whose resistance value is R12) is/are depressed when the processing unit 7 supplies the electric power to the first driving line (331A), and a second-keys result data set that includes results related to the third FSR 32 (whose resistance value is R21) and/or the fourth FSR 32 (whose resistance value is R22) is/are depressed when the processing unit 7 supplies the electric power to the second driving line (331B). The processing unit 7 determines the predetermined threshold value by selecting, from among the value differences respectively of the potential level values, a highest one of value differences and a lowest one of the value differences, determining an average value of the highest one of the value differences and the lowest one of the value differences, and setting the average value as the floating threshold value. It should be noted that, when none of the flexible conductive elements 32 are depressed, theoretically, the value differences respectively of the potential level values are zeros, which cause the floating threshold value to be zero. When the floating threshold value is zero, error in a determination of whether any one of the flexible conductive elements 32 is depressed may occur. Therefore, in order to prevent the error in the determination, the predetermined threshold value is set in advance. In this embodiment, the predetermined threshold value is set to be 20.

For example, when the first FSR 32, whose resistance value is R11, is depressed, the potential level values equivalent respectively to

$$\frac{Vo 1}{Vi 1} , \frac{Vo 2}{Vi 1} , \frac{Vo 1}{Vi 2} , and \frac{Vo 2}{Vi 2}$$

are 1716, 1647, 1647, and 1647, and the value differences between the potential level values and the predetermined potential level value (i.e., 1638) are 78, 9, 9, and 9, respectively. Since the highest one of the difference values is 78 and the lowest one of the difference values is 9, the floating threshold value (i.e., the average value of 78 and 9) is 44. For the first FSR 32, since the value difference between the potential level value and the predetermined potential level value of

$$\frac{Vo 1}{Vi 1}$$

is greater than the predetermined threshold value (i.e., 20 in this embodiment) and is greater than the floating threshold value (i.e., in this case is 44), the processing unit 7 is able to determine that the first FSR 32 is depressed, as may be indicated by the first-key result data set. In another example, when the first FSR 32 and the second FSR 32, whose resistance values are R11 and R12, are depressed at the same time, the potential level values equivalent respectively to

$$\frac{Vo 1}{Vi 1} , \frac{Vo 2}{Vi 1} , \frac{Vo 1}{Vi 2} , and \frac{Vo 2}{Vi 2}$$

are 1724, 1724, 1655, and 1655, and the value differences between the potential level values and the predetermined potential level value are 86, 86, 17, and 17, respectively. Since the highest one of the difference values is 86 and the lowest one of the difference values is 17, the floating threshold value is 52. For the first FSR 32 and the second FSR 32, since the value differences between the potential level values and the predetermined potential level value of

$$\frac{Vo 1}{Vi 1} , \frac{Vo 2}{Vi 1}$$

are both greater than the floating threshold value (i.e., in this case is 52), the processing unit 7 determines that the first FSR 32 and the second FSR 32 are depressed, as may be indicated by the first-keys result data set.

Having stored the first-keys result data set and the second-keys result data set, the processing unit 7 is able to accurately determine, based on the first-keys result data set and the second-keys result data set, which one(s) of the flexible conductive elements 32 is (are) depressed, thereby being able to realize “ghost key” prevention.

In summary, the sensing circuit 3 is disposed on the bottom membrane layer 2 and includes the first circuit 31, the flexible conductive elements 32, and the second circuit 33. The first circuit 31 and the second circuit 33 are spaced apart from each other, and by virtue of having the flexible conductive elements 32 electrically connected between the first circuit 31 and the second circuit 33, which enables the sensing circuit 3 to have a function resembling multiple switches, the anti-ghosting membrane keyboard of this disclosure does not need additional membrane layers to separate the first circuit 31 and the second circuit 33, and also does not need anisotropic conductive adhesive and other materials in order to have the switching function, thereby allowing an overall material cost for manufacturing the anti-ghosting membrane keyboard to be reduced.

In addition, the detecting units 6, the processing unit 7 and the storage unit 8 are able to cooperatively determine which one(s) of the flexible conductive elements 32 is (are) depressed based on a characteristic of the flexible conductive elements 32, where the resistance value of each of the flexible conductive elements 32 changes in response to a force being applied on the flexible conductive element 32. By virtue of the aforementioned arrangements, the anti-ghosting membrane keyboard of this disclosure is able to have the capability of “ghost key” prevention.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. An anti-ghosting membrane keyboard comprising:
a bottom membrane layer;
a sensing circuit including
a first circuit disposed on said bottom membrane layer,
a plurality of flexible conductive elements disposed on said first circuit and spaced apart from each other, each of said plurality of flexible conductive elements being a force-sensing resistor, and
a second circuit disposed on said plurality of flexible conductive elements, said first circuit and said second circuit being spaced apart by said plurality of flexible conductive elements, each of said plurality of flexible conductive elements being connected between a portion of said first circuit and a portion of said second circuit; and
a top membrane layer disposed over said bottom membrane layer and said sensing circuit, and adhered to said bottom membrane layer to cooperatively enclose said sensing circuit.

2. The anti-ghosting membrane keyboard as claimed in claim 1, further comprising:
a middle membrane layer disposed on said bottom membrane layer and said sensing circuit, disposed beneath said top membrane layer, and configured to adhere said bottom membrane layer, said sensing circuit and said top membrane layer to each other.

3. The anti-ghosting membrane keyboard as claimed in claim 1, wherein each of said plurality of flexible conductive elements includes:
a bottom surface in contact with said first circuit;
a top surface opposite to said bottom surface and in contact with said second circuit; and
a lateral surrounding surface interconnecting said bottom surface and said top surface,
wherein, for each of said plurality of flexible conductive elements, a value of resistance thereof reduces when a distance between said top surface and said bottom surface is reduced in response to a force applied onto said top surface.

4. The anti-ghosting membrane keyboard as claimed in claim 1, further comprising a plurality of detecting units electrically connected to said sensing circuit,
wherein said second circuit includes a plurality of driving lines configured to transfer electric power to said plurality of flexible conductive elements, said first circuit includes a plurality of sensing lines and a plurality of voltage divider resistors electrically connected respectively to said plurality of sensing lines, and each of said plurality of flexible conductive elements is electrically connected between one of said plurality of sensing lines and one of said plurality of driving lines,
wherein said plurality of detecting units are electrically connected respectively to said plurality of sensing lines and respectively to said plurality of voltage divider resistors, and are configured for respectively receiving a plurality of divided voltage values that correspond respectively to said plurality of sensing lines.

5. The anti-ghosting membrane keyboard as claimed in claim 4, wherein each of said plurality of sensing lines has a plurality of connection portions that correspond respectively to said plurality of driving lines, and said plurality of flexible conductive elements are disposed respectively on said plurality of connection portions of said plurality of sensing lines.

6. The anti-ghosting membrane keyboard as claimed in claim 4, wherein each of said plurality of sensing lines and a corresponding one of said plurality of voltage divider resistors have a common point, and said plurality of detecting units are electrically connected respectively to the common points between said plurality of sensing lines and said plurality of voltage divider resistors for receiving respectively the plurality of divided voltage values from the common points.

7. The anti-ghosting membrane keyboard as claimed in claim 4, wherein a number of said plurality of detecting units, a number of said plurality of driving lines and a number of said plurality of sensing lines are the same.

8. The anti-ghosting membrane keyboard as claimed in claim 4, further comprising a processing unit electrically connected to said plurality of detecting units and said plurality of driving lines, and configured to supply the electric power to said plurality of driving lines one by one,
wherein, each time said processing unit supplies the electric power to one of said plurality of driving lines, for each of said plurality of detecting units, said detecting unit is further configured to, in response to receipt of one of the plurality of divided voltage values from a corresponding one of said plurality of sensing lines, obtain a potential level value based on said one of the plurality of divided voltage values thus received, and transmit the potential level value thus obtained to said processing unit, and said processing unit is further configured to calculate a value difference between the potential level value thus received and a predetermined potential level value.

9. The anti-ghosting membrane keyboard as claimed in claim 8, wherein said processing unit is further configured to, after calculating the value difference, determine whether the value difference is greater than a predetermined threshold value and a floating threshold value.

10. The anti-ghosting membrane keyboard as claimed in claim 9, wherein, for one of said plurality of flexible conductive elements that is electrically connected to the corresponding one of said plurality of sensing lines from which said one of the plurality of divided voltage values is received and that is electrically connected to one of said plurality of driving lines to which said processing unit is supplying the electric power,
said processing unit is further configured to determine that said one of said plurality of flexible conductive elements is depressed in response to determining that the value difference is greater than the predetermined threshold value and the floating threshold value.

11. The anti-ghosting membrane keyboard as claimed in claim 4, wherein each of said plurality of detecting units is an analog-to-digital converter.
